(19) United States
(12) Patent Application Publication
(10) Pub. No.: US 2024/0204142 A1
(43) Pub. Date: Jun. 20, 2024

(54) DISPLAY DEVICE

(71) Applicant: Samsung Display Co., Ltd., Yongin-si (KR)

(72) Inventors: JUNGSUN PARK, Yongin-si (KR); HYE JIN GWARK, Yongin-si (KR); JAEIK KIM, Yongin-si (KR); HWI KIM, Yongin-si (KR); DUCKJUNG LEE, Yongin-si (KR); YEONHWA LEE, Yongin-si (KR); JOONGU LEE, Yongin-si (KR)

(21) Appl. No.: 18/223,050

(22) Filed: Jul. 18, 2023

(30) Foreign Application Priority Data
Dec. 16, 2022 (KR) 10-2022-0177378

(51) Int. Cl. H01L 33/42; H01L 25/075; H01L 25/16; H01L 33/62

(52) U.S. Cl. CPC H01L 33/42; H01L 25/0753; H01L 25/167; H01L 33/62

(57) ABSTRACT

A display device includes a substrate, a transistor disposed on the substrate, a power electrode disposed on the substrate, a pixel electrode disposed on the transistor, a light emitting layer disposed on each of the pixel electrode and the power electrode, and a common electrode disposed on the light emitting layer. The power electrode includes a stem part extending in a first direction and at least one first branch part protruding from the stem part in a second direction crossing the first direction in a plan view. The first branch part has a shape in which a width decreases as a distance from the stem part increases in a plan view.

### CROSS-REFERENCE TO RELATED APPLICATION(S)

This application claims priority under 35 USC § 119 to Korean Patent Application No. 10-2022-0177378 filed on Dec. 16, 2022, in the Korean Intellectual Property Office (KIPO), the entire disclosure of which is incorporated by reference herein.

### BACKGROUND

### 1. Field

Embodiments relate to a display device. More specifically, embodiments relate to a display device with improved display quality.

### 2. Description of the Related Art

As information technology develops, the importance of display devices, which are communication media between users and information, is being highlighted. Accordingly, display devices such as liquid crystal display devices, organic light emitting display devices, plasma display devices, or the like are widely used in various fields.

The display device may include light emitting elements, and the light emitting elements may include a pixel electrode, a common electrode and a light emitting layer disposed therebetween. The common electrode may be formed of a plate electrode. As a size of the display device increases, a voltage provided to the common electrode may drop. Accordingly, a structure for preventing a drop in the voltage provided to the common electrode is being developed.

### SUMMARY

Embodiments provide a display device with improved display quality.

A display device according to an embodiment of the present disclosure includes a substrate, a transistor disposed on the substrate, a power electrode disposed on the substrate, a pixel electrode disposed on the transistor, a light emitting layer disposed on each of the pixel electrode and the power electrode, and a common electrode disposed on the light emitting layer. The power electrode includes a stem part extending in a first direction and at least one first branch part protruding from the stem part in a second direction crossing the first direction in a plan view. The first branch part has a shape in which a width decreases as a distance from the stem part increases in a plan view.

In an embodiment, the power electrode may further include at least one second branch part protruding from the stem part in a third direction opposite to the second direction in a plan view.

In an embodiment, the first branch part and the second branch part may be symmetrical to each other with respect to the stem part in a plan view.

In an embodiment, the first branch part and the second branch part may be asymmetrical to each other with respect to the stem part in a plan view.

In an embodiment, the power electrode may include a first electrode layer, a second electrode layer disposed on the first electrode layer and a third electrode layer disposed on the second electrode layer. A side surface of the first electrode layer may protrude from a side surface of the second electrode layer.

In an embodiment, a side surface of the third electrode layer may protrude from the side surface of the second electrode layer.

In an embodiment, the side surface of the second electrode layer may form an angle of about 10 degrees or more and about 150 degrees or less with respect to an upper surface of the first electrode layer in a cross-sectional view.

In an embodiment, the light emitting layer may include a first light emitting layer disposed on the pixel electrode and a second light emitting layer disposed on the power electrode and spaced apart from the first light emitting layer. The first light emitting layer may contact the side surface of the second electrode layer.

In an embodiment, the common electrode may include a first common electrode disposed on the first light emitting layer and covering the first light emitting layer and a second common electrode disposed on the power electrode and spaced apart from the first common electrode. The first common electrode may contact the side surface of the second electrode layer.

In an embodiment, the power electrode may further include at least one fourth electrode layer disposed on the third electrode layer and at least one fifth electrode layer disposed on the fourth electrode layer. A side surface of the third electrode layer may protrude from a side surface of the fourth electrode layer.

In an embodiment, at least one of the first, second and third electrode layers may include a metal.

In an embodiment, at least one of the first, second and third electrode layers may include a transparent conductive oxide.

In an embodiment, at least one of the first, second and third electrode layers may include an organic material.

In an embodiment, a ratio of a length of the power electrode in the first direction to a length of the power electrode in the second direction in a plan view may be about 1:20 to about 20:1.

A display device according to an embodiment of the present disclosure includes a substrate, a transistor disposed on the substrate, a power electrode disposed on the substrate, a pixel electrode disposed on the transistor, a light emitting layer disposed on each of the pixel electrode and the power electrode, and a common electrode disposed on the light emitting layer. The power electrode includes a stem part extending in a first direction and a branch part protruding from the stem part in a plan view. The branch part includes at least one first branch part protruding in a second direction crossing the first direction and at least one second branch part protruding in a third direction crossing at least one of the first direction and the second direction.

In an embodiment, the power electrode may include a first electrode layer, a second electrode layer disposed on the first electrode layer and a third electrode layer disposed on the second electrode layer. A side surface of the first electrode layer may protrude from a side surface of the second electrode layer.

In an embodiment, a side surface of the third electrode layer may protrude from the side surface of the second electrode layer.

In an embodiment, the side surface of the second electrode layer may form an angle of about 10 degrees or more and about 150 degrees or less with respect to an upper surface of the first electrode layer in a cross-sectional view.

In an embodiment, the light emitting layer may include a first light emitting layer disposed on the pixel electrode and a second light emitting layer disposed on the power electrode and spaced apart from the first light emitting layer. The first light emitting layer may contact the side surface of the second electrode layer.

In an embodiment, the common electrode may include a first common electrode disposed on the first light emitting layer and covering the first light emitting layer and a second common electrode disposed on the power electrode and spaced apart from the first common electrode. The first common electrode may contact the side surface of the second electrode layer.

In a display device according to embodiments of the present disclosure, the display device may include a power electrode and a common electrode. The power electrode may include a first electrode layer, a second electrode layer disposed on the first electrode layer and a third electrode layer disposed on the second electrode layer. A side surface of the first electrode layer may protrude from a side surface of the second electrode layer. The common electrode may be connected to the power electrode by contacting the side surface of the second electrode layer. Accordingly, a voltage drop in the common electrode may be prevented. In addition, since the common electrode may be connected to the power electrode without a separate laser drilling process or a photo process using a separate mask, an efficiency of a manufacturing process may be improved.

In addition, the power electrode may include a stem part extending in a first direction and at least one branch part protruding from the stem part in a plan view. Accordingly, a contact area between the power electrode and the common electrode may increase, and contact resistance of the common electrode to the power electrode may decrease. Accordingly, the voltage drop in the common electrode may be prevented, and display quality of the display device may be improved.

### BRIEF DESCRIPTION OF THE DRAWINGS

FIG. 1 is a plan view illustrating a display device according to an embodiment of the present disclosure.

FIG. 2 is a cross-sectional view of a portion of the display device of FIG. 1.

FIG. 3 is an enlarged cross-sectional view of area A of FIG. 2.

FIG. 4 is a plan view illustrating an example of a power electrode included in the display device of FIG. 2.

FIGS. 5, 6, 7, 8, 9, 10 and 11 are plan views illustrating other examples of FIG. 4.

FIGS. 12, 13, 14, 15, 16, 17, 18, 19, 20 and 21 are cross-sectional views for explaining a method of manufacturing the display device of FIG. 2.

FIG. 22 is a cross-sectional view illustrating another example of FIG. 3.

FIG. 23 is a cross-sectional view illustrating a portion of a display device according to another embodiment of the present disclosure.

FIG. 24 is an enlarged cross-sectional view of area F of FIG. 23.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

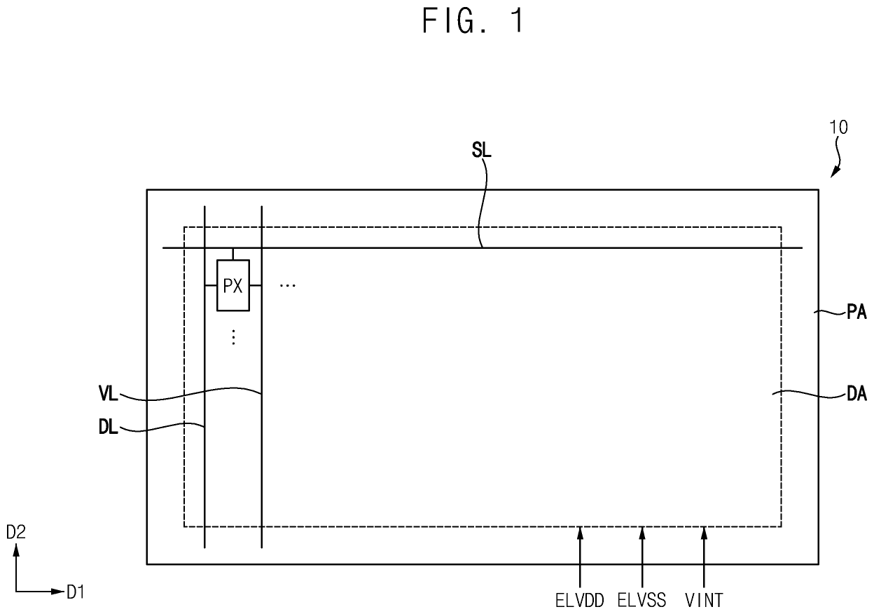

FIG. 1 is a plan view illustrating a display device according to an embodiment of the present disclosure.

Referring to FIG. 1, a display device 10 may include a display area DA and a peripheral area PA.

The display area DA may be an area capable of displaying an image by generating light. Pixels PX for displaying an image may be disposed in the display area DA. The pixels PX may be arranged in a matrix form along a first direction D1 and a second direction D2 crossing the first direction D1. For example, the second direction D2 may be perpendicular to the first direction D1. The pixels PX may include a light emitting element and a pixel circuit for driving the light emitting element. In an embodiment, the light emitting element may include an organic light emitting diode, and the pixel circuit may include at least one thin film transistor.

Lines for providing signals or power to the pixels PX may be disposed in the display area DA. For example, a scan line SL, a data line DL and a power line VL may be disposed in the display area DA.

The scan line SL may extend along the first direction D1 and may supply scan signals to the pixels PX. The data line DL may extend along the second direction D2 and may supply data signals to the pixels PX. The power line VL may extend along the second direction D2 parallel to the data line DL and may supply a power voltage to the pixels PX.

To drive the pixels PX, a first power voltage ELVDD, a second power voltage ELVSS and an initialization voltage VINT may be applied to the pixels PX. In this case, the second power voltage ELVSS may be applied to the power line VL.

The peripheral area PA may be an area not displaying an image. The peripheral area PA may surround at least a portion of the display area DA. For example, the peripheral area PA may entirely surround the display area DA. A driving circuit for driving the display device 10, an inspection circuit for inspecting the display device 10, or the like may be disposed in the peripheral area PA. For example, the power line VL may extend from the display area DA to the peripheral area PA, and may be connected to a test pad (not shown) disposed in the peripheral area PA.

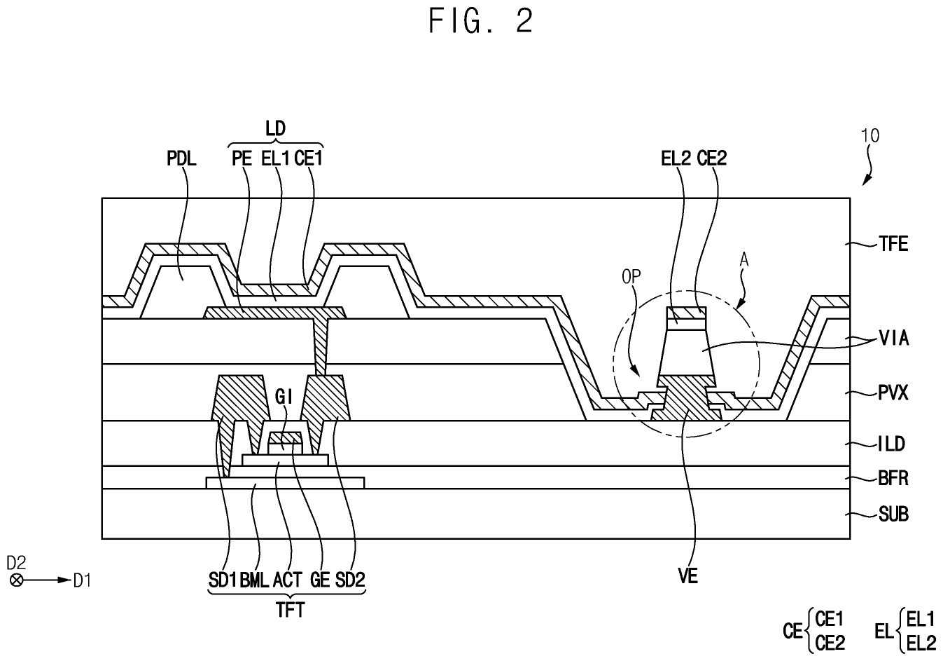

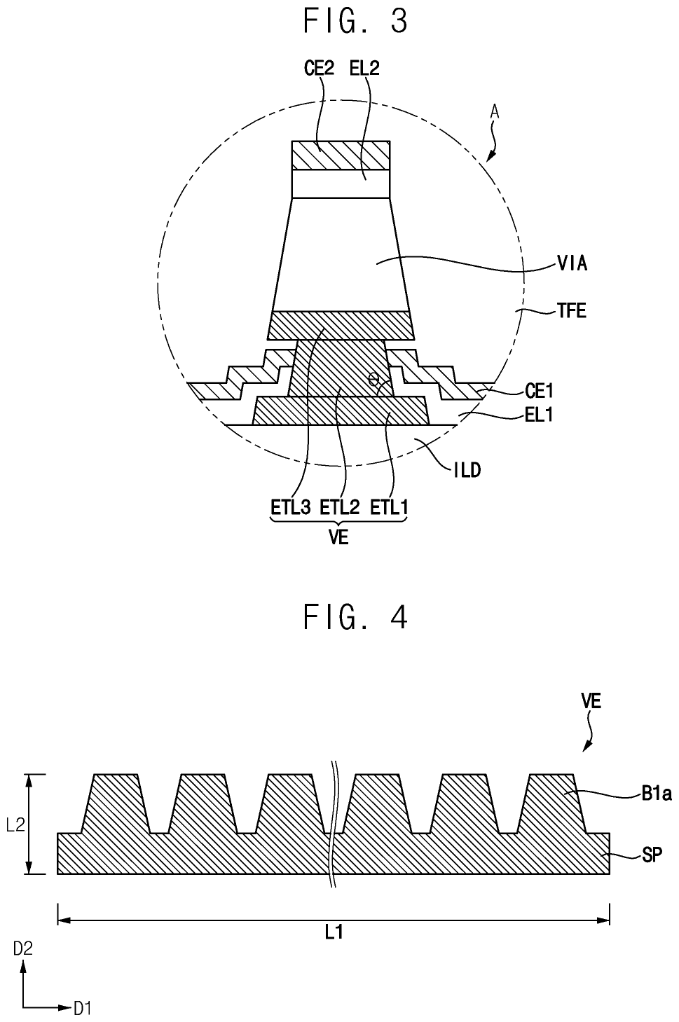

FIG. 2 is a cross-sectional view of a portion of the display device of FIG. 1. FIG. 3 is an enlarged cross-sectional view of area A of FIG. 2. For example, FIG. 3 may be an enlarged cross-sectional view of a power electrode VE included in the display device 10.

Referring to FIGS. 1, 2 and 3, the display device 10 may include a substrate SUB, a lower metal pattern BML, a buffer layer BFR, an active pattern ACT, a gate insulating layer GI, a gate electrode GE, an interlayer insulating layer ILD, a first connection electrode SD1, a second connection electrode SD2, a power electrode VE, a passivation layer PVX, a via insulating layer VIA, a pixel electrode PE, a pixel defining layer PDL, a light emitting layer EL, a common electrode CE and a thin film encapsulation layer TFE.

The substrate SUB may include a transparent or opaque material. Examples of materials that may be used as the substrate SUB may include glass, quartz, plastic, or the like. These may be used alone or in combination with each other.

The lower metal pattern BML may be disposed on the substrate SUB. The lower metal pattern BML may include a conductive material. Examples of conductive materials that may be used as the lower metal pattern BML may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. In addition, the lower metal pattern BML may be configured as a single layer or a multi-layer.

The buffer layer BFR may be disposed on the substrate SUB, and may cover the lower metal pattern BML. The buffer layer BFR may prevent diffusion of impurities such as oxygen and moisture to an upper portion of the substrate SUB. The buffer layer BFR may include an inorganic insulating material. Examples of inorganic insulating materials that may be used as the buffer layer BFR may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), or the like. These may be used alone or in combination with each other. In addition, the buffer layer BFR may be configured as a single layer or a multi-layer.

The active pattern ACT may be disposed on the buffer layer BFR. The active pattern ACT may include a source area, a drain area and a channel area positioned between the source area and the drain area. The active pattern ACT may include a silicon semiconductor material or an oxide semiconductor material. Examples of silicon semiconductor materials that may be used as the active pattern ACT may include amorphous silicon, polycrystalline silicon, or the like. Examples of oxide semiconductor materials that may be used as the active pattern ACT may include indium gallium zinc oxide (IGZO), indium tin zinc oxide (ITZO), or the like. These may be used alone or in combination with each other.

The gate insulating layer GI may be disposed on the active pattern ACT. The gate insulating layer GI may include an inorganic insulating material. Examples of inorganic insulating materials that may be used as the gate insulating layer GI may include silicon oxide, silicon nitride, silicon oxynitride, or the like. These may be used alone or in combination with each other. The gate insulating layer GI may be a patterned insulating layer disposed to overlap the channel area of the active pattern ACT in a plan view.

The gate electrode GE may be disposed on the gate insulating layer GI. The gate electrode GE may overlap the channel area of the active pattern ACT. The gate electrode GE may include a conductive material. Examples of conductive materials that may be used as the gate electrode GE may include aluminum (Al), platinum (Pt), palladium (Pd), silver (Ag), magnesium (Mg), gold (Au), nickel (Ni), neodium (Nd), iridium (Ir), chromium (Cr), lithium (Li), calcium (Ca), molybdenum (Mo), titanium (Ti), tungsten (W), copper (Cu), or the like. These may be used alone or in combination with each other.

The interlayer insulating layer ILD may be disposed on the buffer layer BFR. The interlayer insulating layer ILD may cover the active pattern ACT, the gate insulating layer GI and the gate electrode GE. The interlayer insulating layer ILD may include an inorganic insulating material. Examples of inorganic insulating materials that may be used as the interlayer insulating layer ILD may include silicon oxide, silicon nitride, silicon oxynitride, or the like. These may be used alone or in combination with each other.

The first connection electrode SD1 and the second connection electrode SD2 may be disposed on the interlayer insulating layer ILD. The first connection electrode SD1 may be electrically connected to the active pattern ACT through a contact hole formed through a portion of the interlayer insulating layer ILD. In addition, the first connection electrode SD1 may be electrically connected to the lower metal pattern BML through a contact hole formed through portions of the interlayer insulating layer ILD and the buffer layer BFR. The second connection electrode SD2 may be electrically connected to the active pattern ACT through a contact hole formed through a portion of the interlayer insulating layer ILD. Each of the first connection electrode SD1 and the second connection electrode SD2 may include a conductive material. Examples of conductive materials that may be used as each of the first connection electrode SD1 and the second connection electrode SD2 may include aluminum, platinum, palladium, silver, magnesium, gold, nickel, neodymium, iridium, chromium, lithium, calcium, molybdenum, titanium, tungsten, copper, or the like. These may be used alone or in combination with each other. In an embodiment, each of the first connection electrode SD1 and the second connection electrode SD2 may be configured as a multi-layer.

The lower metal pattern BML, the active pattern ACT, the gate electrode GE, the first connection electrode SD1 and the second connection electrode SD2 may constitute a thin film transistor TFT.

The power electrode VE may be disposed on the interlayer insulating layer ILD. The power electrode VE may be spaced apart from the thin film transistor TFT. In an embodiment, the power electrode VE may be formed together with the first connection electrode SD1 and the second connection electrode SD2. In other words, the power electrode VE may be disposed on a same layer as the first connection electrode SD1 and the second connection electrode SD2, and may be formed using a same material and a same process as the first connection electrode SD1 and the second connection electrode SD2.

The power electrode VE may be a portion of the power line VL. That is, the power line VL may include the power electrode VE. Accordingly, the second power voltage ELVSS may be applied to the power electrode VE.

The power electrode VE may include a first electrode layer ETL1, a second electrode layer ETL2 disposed on the first electrode layer ETL1 and a third electrode layer ETL3 disposed on the second electrode layer ETL2.

In an embodiment, a side surface of the first electrode layer ETL1 may protrude from a side surface of the second electrode layer ETL2. In addition, a side surface of the third electrode layer ETL3 may protrude from the side surface of the second electrode layer ETL2. The power electrode VE may have an undercut portion in the second electrode layer ETL2. However, the present disclosure is not limited thereto. A length in which the side surface of the third electrode layer ETL3 protrudes from the side surface of the second electrode layer ETL2 may be variously changed according to an incident angle of the common electrode, a contact area between the common electrode and the power supply electrode, or the like.

In an embodiment, the second electrode layer ETL2 may have a tapered or reverse tapered shape with respect to the first electrode layer ETL1 in cross-sectional view. Specifically, an angle θ of the side surface of the second electrode layer ETL2 with respect to an upper surface of the first electrode layer ETL1 in cross-sectional view may be about 10 degrees or more and about 150 degrees or less.

Each of the first, second and third electrode layers ETL1, ETL2 and ETL3 may include materials different from each other. However, the present disclosure is not limited thereto. For example, each of the first, second and third electrode layers ETL1, ETL2 and ETL3 may include a same material as each other.

In an embodiment, at least one electrode layer among the first, second and third electrode layers ETL1, ETL2 and ETL3 may include a metal. For example, each of the first electrode layer ETL1 and the third electrode layer ETL3 may include titanium, and the second electrode layer ETL2 may include aluminum, but the present disclosure is not limited thereto.

In another embodiment, at least one electrode layer among the first, second and third electrode layers ETL1, ETL2 and ETL3 may include a transparent conductive oxide (TCO). For example, the first, second and third electrode layers ETL1, ETL2 and ETL3 may include indium tin oxide, but the present disclosure is not limited thereto.

In still another embodiment, at least one electrode layer among the first, second and third electrode layers ETL1, ETL2 and ETL3 may include an organic material. For example, the third electrode layer ETL3 may include an organic material, but the present disclosure is not limited thereto.

The passivation layer PVX may be disposed on the interlayer insulating layer ILD. The passivation layer PVX may cover the first connection electrode SD1 and the second connection electrode SD2. An opening exposing a portion of an upper surface of the interlayer insulating layer ILD and the power electrode VE may be defined in the passivation layer PVX. The passivation layer PVX may include an inorganic insulating material. Examples of insulating materials that may be used as the passivation layer PVX may include silicon oxide, silicon nitride, silicon oxynitride, or the like. These may be used alone or in combination with each other. In addition, the passivation layer PVX may be configured as a single layer or a multi-layer.

The via insulating layer VIA may be disposed on each of the passivation layer PVX and the power electrode VE. An opening exposing a portion of the upper surface of the interlayer insulating layer ILD and the power electrode VE may be defined in the via insulating layer VIA. The via insulating layer VIA may include an organic insulating material. Examples of insulating materials that may be used as the via insulating layer VIA may include photoresist, polyacrylic resin, polyimide resin, acrylic resin, or the like. These may be used alone or in combination with each other.

The opening defined in the passivation layer PVX and the opening defined in the via insulating layer VIA may define an opening OP exposing a portion of the upper surface of the interlayer insulating layer ILD and the power electrode VE. The via insulating layer VIA disposed on the power electrode VE disposed in the opening OP may have a pattern shape. The via insulating layer VIA having the pattern shape may be spaced apart from the rest of the via insulating layer VIA. However, the present disclosure is not limited thereto.

A light emitting diode LD, which includes the pixel electrode PE, the light emitting layer EL, and the common electrode CE, may be formed on the via insulating layer VIA. The pixel electrode PE may be disposed on the via insulating layer VIA. The pixel electrode PE may be spaced apart from the power electrode VE. The pixel electrode PE may be electrically connected to the thin film transistor TFT through a contact hole formed through the passivation layer PVX and the via insulating layer VIA. The pixel electrode PE may include a conductive material. Examples of conductive materials that may be used as the pixel electrode PE may include aluminum, platinum, palladium, silver, magnesium, gold, nickel, neodymium, iridium, chromium, lithium, calcium, molybdenum, titanium, tungsten, copper, indium tin oxide, indium zinc oxide, or the like. These may be used alone or in combination with each other.

The pixel defining layer PDL may be disposed on the via insulating layer VIA. An opening exposing at least a portion of an upper surface of the pixel electrode PE may be defined in the pixel defining layer PDL. The pixel defining layer PDL may include an organic insulating material. Examples of organic insulating materials that may be used as the pixel defining layer PDL may include photoresist, polyacrylic resin, polyimide resin, acrylic resin, or the like. These may be used alone or in combination with each other.

The light emitting layer EL may be disposed on the pixel electrode PE, the pixel defining layer PDL and the via insulating layer VIA. In addition, the light emitting layer EL may be disposed on the interlayer insulating layer ILD and the power electrode VE exposed by the opening OP. The light emitting layer EL may emit light of a predetermined color. The light emitting layer EL may include an organic light emitting layer including an organic material. In addition, the light emitting layer EL may further include an auxiliary layer for assisting light emitting. The auxiliary layer may include at least one of a hole injection layer, a hole transport layer, an electron transport layer and an electron injection layer.

The light emitting layer EL may include a first light emitting layer EL1 and a second light emitting layer EL2 spaced apart from the first light emitting layer EL1. For example, the first light emitting layer EL1 may be disposed on the pixel electrode PE, the pixel defining layer PDL and the interlayer insulating layer ILD. In other words, the first light emitting layer EL1 may extend from the upper surface of the interlayer insulating layer ILD exposed by the opening OP to an upper surface of the pixel defining layer PDL along the opening OP. The first light emitting layer EL1 may include the organic light emitting layer and the auxiliary layer.

The second light emitting layer EL2 may be disposed on the power electrode VE. The second light emitting layer EL2 may include only the auxiliary layer. In other words, the second light emitting layer EL2 may include at least one of the hole injection layer, the hole transport layer, the electron transport layer and the electron injection layer, and may not include the organic light emitting layer. However, the present disclosure is not limited thereto.

In an embodiment, the first light emitting layer EL1 may contact the power electrode VE. Specifically, the first light emitting layer EL1 may contact the side surface of each of the first electrode layer ETL1 and the second electrode layer ETL2.

The common electrode CE may be disposed on the light emitting layer EL. The common electrode CE may include a conductive material. Examples of conductive materials that may be used as the common electrode CE may include aluminum, platinum, silver, magnesium, gold, chromium, tungsten, titanium, or the like. These may be used alone or in combination with each other. In addition, the common electrode CE may be configured as a single layer or a multi-layer.

The common electrode CE may include a first common electrode CE1 and a second common electrode CE2 spaced apart from the first common electrode CE1. For example, the first common electrode CE1 may be disposed on the first light emitting layer EL1, and the second common electrode CE2 may be disposed on the second light emitting layer EL2. The first common electrode CE1 may cover the first light emitting layer EL1. In other words, the first common electrode CE1 may be disposed along a profile of the first light emitting layer EL1.

In an embodiment, the first common electrode CE1 may contact the power electrode VE. Specifically, the first common electrode CE1 may contact the side surface of the second electrode layer ETL2. As the length in which the side surface of the third electrode layer ELT3 protrudes from the side surface of the second electrode layer ETL2 increases, a contact area between the first common electrode CE1 and the side surface of the second electrode layer ETL2 may increase. Accordingly, the first common electrode CE1 may be electrically connected to the power line VL.

The thin film encapsulation layer TFE may be disposed on the common electrode CE. The thin film encapsulation layer TFE may prevent penetration of external moisture and oxygen to the light emitting diode LD. In an embodiment, the thin film encapsulation layer TFE may include at least one organic layer and at least one inorganic layer. For example, the organic layer and the inorganic layer may be alternately stacked. In another embodiment, the thin film encapsulation layer TFE may be provided as an encapsulation substrate.

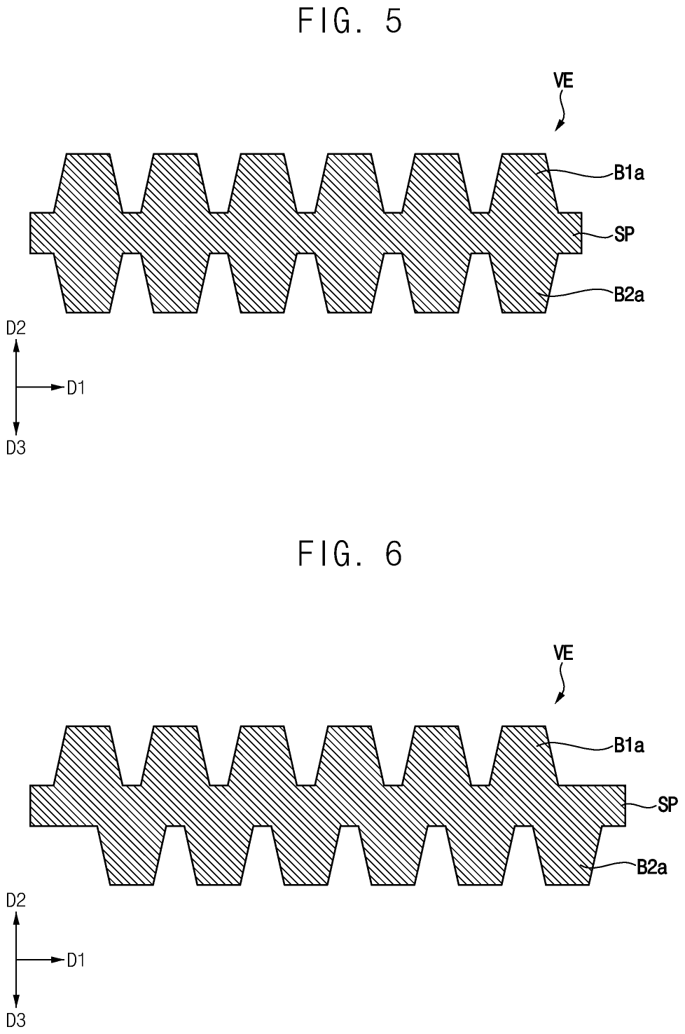

FIG. 4 is a plan view illustrating an example of the power electrode included in the display device of FIG. 2.

Referring to FIG. 4, the power electrode VE may include a stem part SP and at least one first branch part B1a.

The stem part SP may extend in the first direction D1. The first branch part B1a may protrude from the stem part SP in the second direction D2. In an embodiment, the first branch part B1a may have a shape in which a width decreases as a distance from the stem part SP increases in a plan view. In other words, the first branch part B1a may have the shape in which the width decreases along the second direction D2.

In an embodiment, a ratio of a length L1 of the power electrode VE in the first direction D1 to a length L2 of the power electrode VE in the second direction D2 in a plan view may be about 1:20 to about 20:1.

FIGS. 5, 6, 7, 8, 9, 10 and 11 are plan views illustrating other examples of FIG. 4.

Hereinafter, descriptions overlapping those of the power electrode VE described with reference to FIG. 4 will be omitted or simplified.

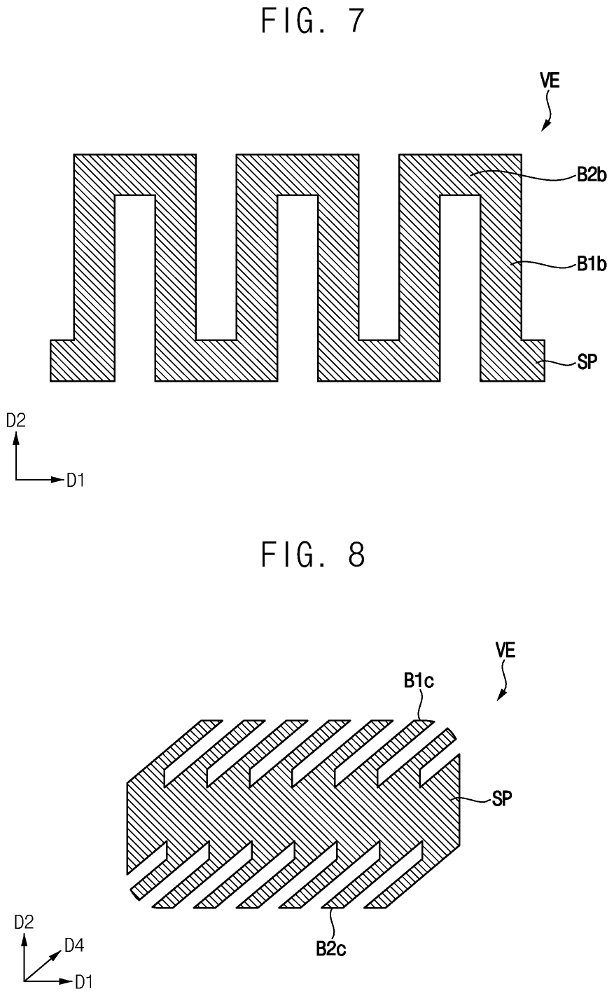

Referring to FIGS. 5 and 6, the power electrode VE may include the stem part SP, the first branch part B1a and at least one second branch part B2a.

The first branch part B1a may protrude from the stem part SP in the second direction D2 and the second branch part B2a may protrude from the stem part SP in a third direction D3. For example, the third direction D3 may be an opposite direction to the second direction D2.

In an embodiment, each of the first branch part B1a and the second branch part B2a may have a shape in which a width decreases as a distance from the stem part SP increases in a plan view. In other words, the first branch part B1a may have the shape in which the width decreases along the second direction D2 and the second branch part B2a may have the shape in which the width decreases along the third direction D3.

In an embodiment, the first branch part B1a and the second branch part B2a may be symmetrical to each other with respect to the stem part SP in a plan view. In another embodiment, the first branch part B1a and the second branch part B2a may be asymmetrical to each other with respect to the stem part SP in a plan view.

Referring to FIG. 7, the power electrode VE may include the stem part SP, at least one first branch part B1b and at least one second branch part B2b.

The first branch part B1b may protrude from the stem part SP in the second direction D2. Specifically, the second branch part B2b may connect ends of the first branch parts B1b disposed adjacent each other in the first direction and may extend from the first branch part B1b in the first direction D1. That is, the power electrode VE may have a zigzag shape in a plan view.

Referring to FIG. 8, the power electrode VE may include the stem part SP, at least one first branch part B1c and at least one second branch part B2c.

The first branch part B1c may protrude from the stem part SP in a fourth direction D4. The fourth direction D4 may cross each of the first direction D1 and the second direction D2. For example, the fourth direction D4 may be a direction between the first direction D1 and the second direction D2. The second branch part B2c may protrude from the stem part SP in a direction opposite to the fourth direction D4.

In an embodiment, a width of each of the first branch part B1c and the second branch part B2c disposed adjacent to the stem part SP may be greater than a width of each of the first branch part B1c and the second branch part B2c disposed away from the stem part SP. However, the present disclosure is not limited thereto. In another embodiment, the width of each of the first branch part B1c and the second branch part B2c may have a uniform width. In still another embodiment, the width of each of the first branch part B1c and the second branch part B2c disposed adjacent to the stem part SP may be smaller than the width of each of the first branch part B1c and the second branch part B2c disposed away from the stem part SP.

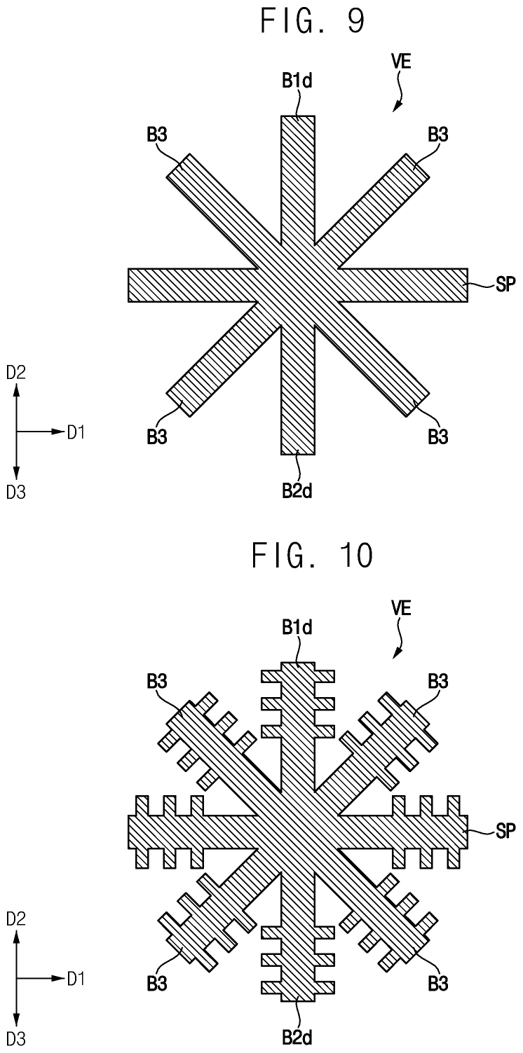

Referring to FIGS. 9, 10 and 11, the power electrode VE may include the stem part SP, a first branch part B1d, a second branch part B2d and at least one third branch part B3.

The first branch part B1d may protrude from the stem part SP in the second direction D2. The second branch part B2d may protrude from the stem part SP in the third direction D3 opposite to the second direction D2.

The third branch part B3 may protrude from the stem part SP in a direction crossing each of the first direction D1, the second direction D2 and the third direction D3. For example, the third branch part B3 may protrude from the stem part SP in a direction between the first direction D1 and the second direction D2. The third branch part B3 may protrude from the stem part SP in a direction between the first direction D1 and the third direction D3. The third branch part B3 may protrude from the stem part SP in a direction between the second direction D2 and the third direction D3.

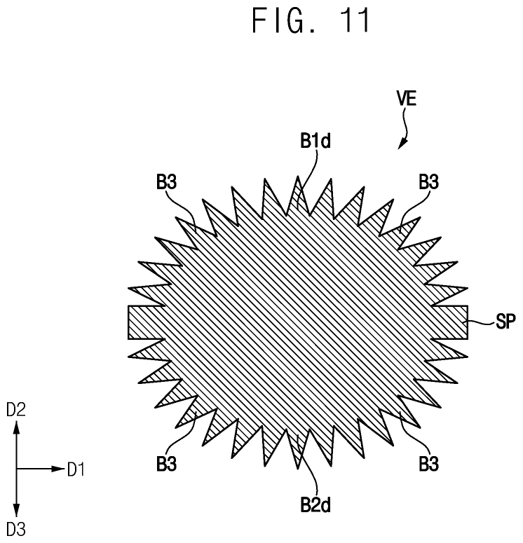

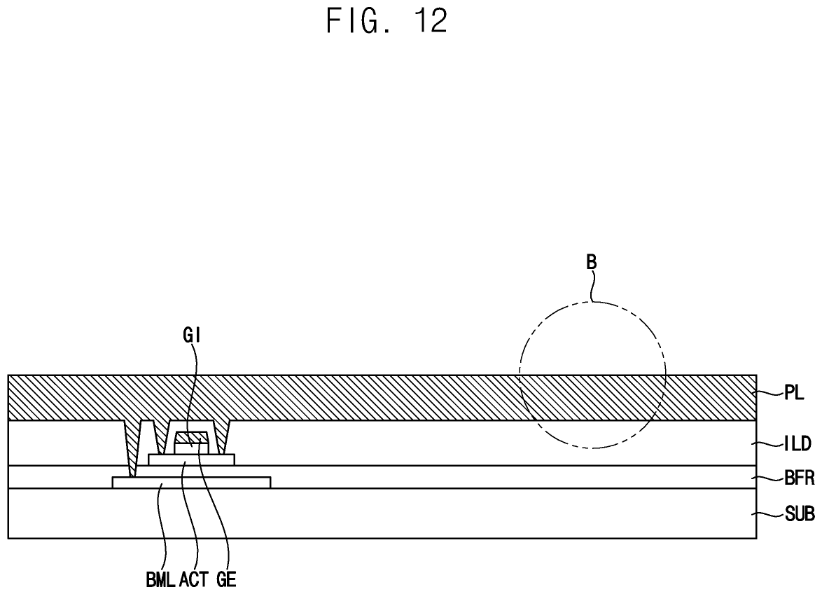

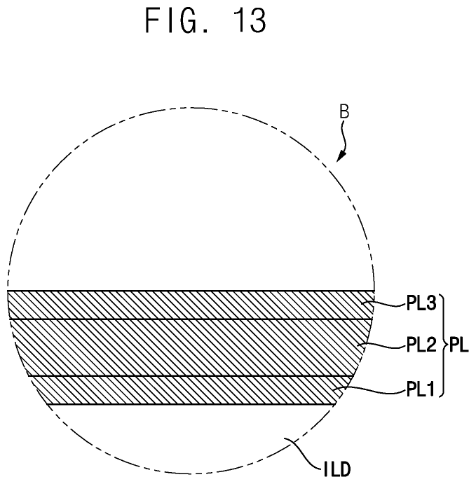

Each of the first, second and third branch parts B1d, B2d and B3 may have various shapes. In an embodiment, the first, second and third branch parts B1d, B2d and B3 may have a same shape as each other. For example, each of the first, second and third branch parts B1d, B2d and B3 may have a rectangular shape in a plan view (see FIG. 9). For another example, each of the first, second and third branch parts B1d, B2d and B3 may further include protrusions protruding from the first, second and third branch parts B1d, B2d and B3 to both sides of the first, second and third branch parts B1d, B2d and B3 in a direction perpendicular to the first, second and third branch parts B1d, B2d and B3 (see FIG. 10). For still another example, each of the first, second and third branch parts B1d, B2d and B3 may have a shape in which a width decreases as a distance from the stem part SP increases in a plan view. In other words, the power electrode VE may have a gear shape in a plan view (see FIG. 11). In another embodiment, the first, second and third branch parts B1d, B2d and B3 may have different shapes from each other.

The display device 10 according to an embodiment of the present disclosure may include the power electrode VE including the first electrode layer ETL1, the second electrode layer ETL2 and the third electrode layer ETL3, and the common electrode CE connected to the power electrode VE. The side surface of the first electrode layer ETL1 may protrude from the side surface of the second electrode layer ETL2. The common electrode CE may be connected to the power electrode VE by contacting the side surface of the second electrode layer ETL2. Because the power electrode VE has a good electrical conductivity and is thicker than the common electrode, a voltage drop in the common electrode CE may be prevented. In addition, since the common electrode CE may be connected to the power electrode VE without a separate laser drilling process or a photo process using a separate mask, an efficiency of a manufacturing process may be improved.

In addition, the power electrode VE may include the stem part SP extending in the first direction D1 in a plan view and at least one branch part protruding from the stem part SP. Accordingly, a contact area between the power electrode VE and the common electrode CE may increase, and contact resistance of the common electrode CE to the power electrode VE may decrease. Accordingly, the voltage drop in the common electrode CE may be prevented, and display quality of the display device 10 may be improved.

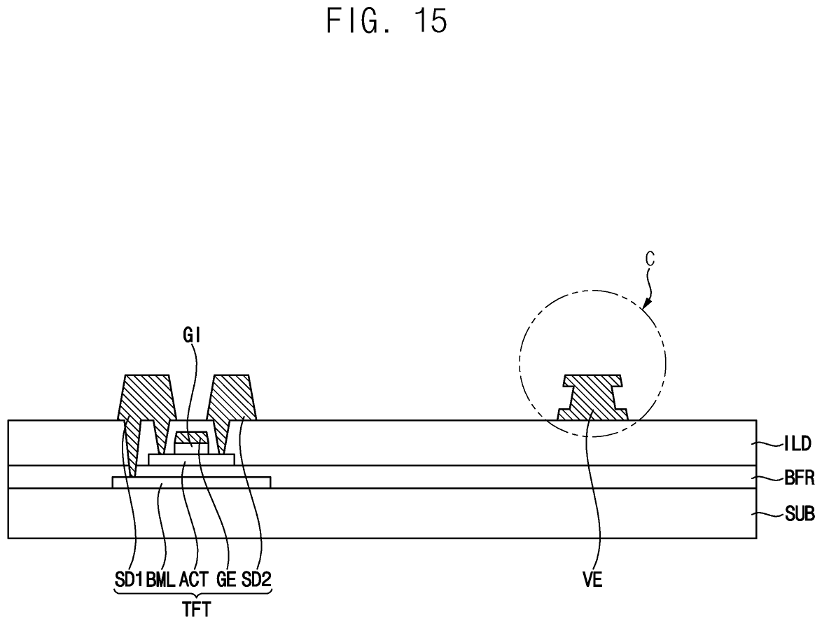

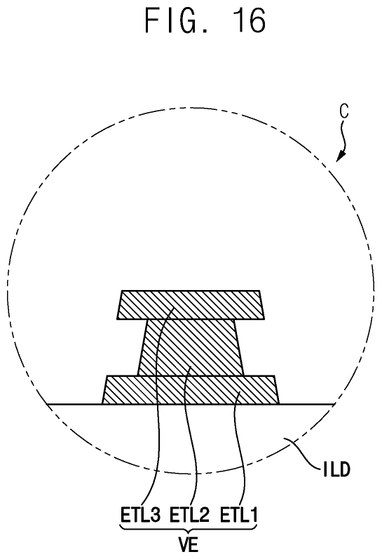

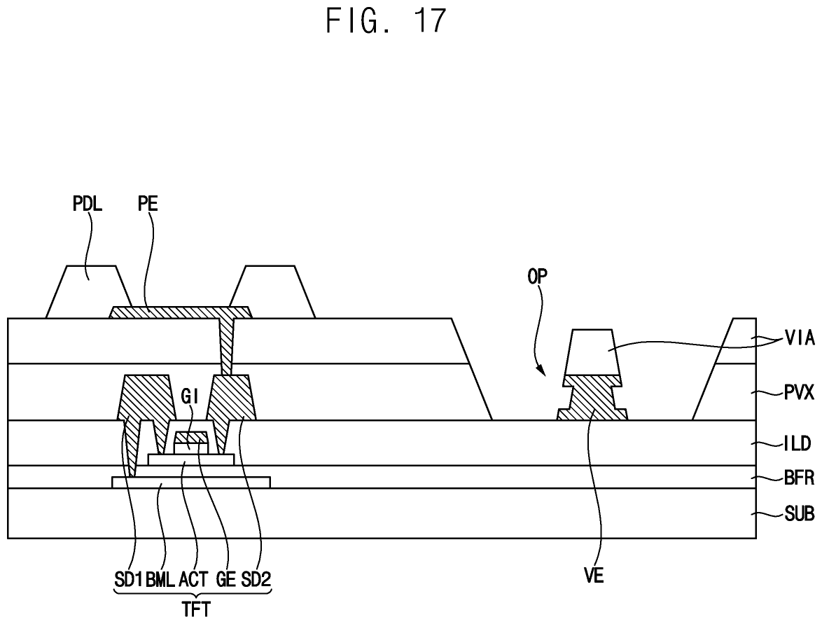

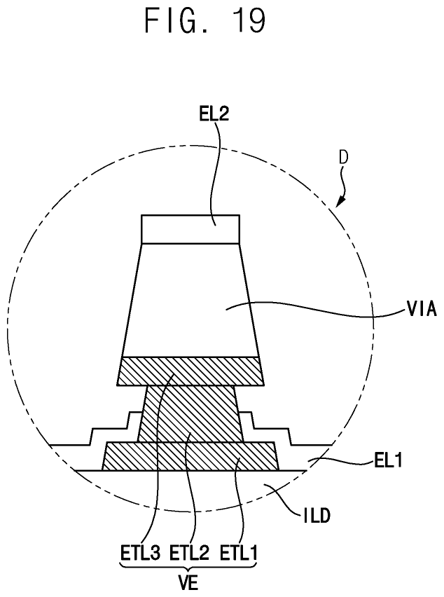

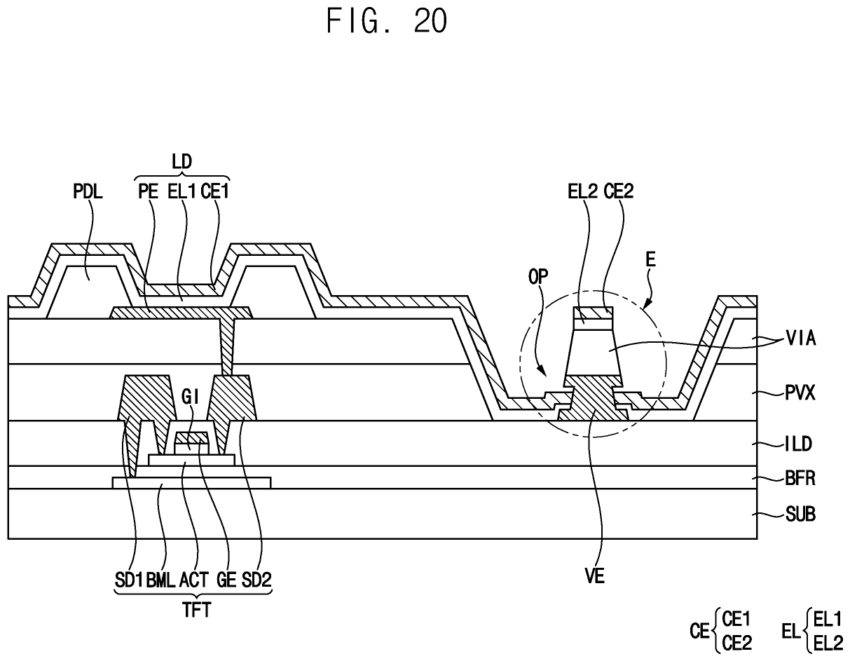

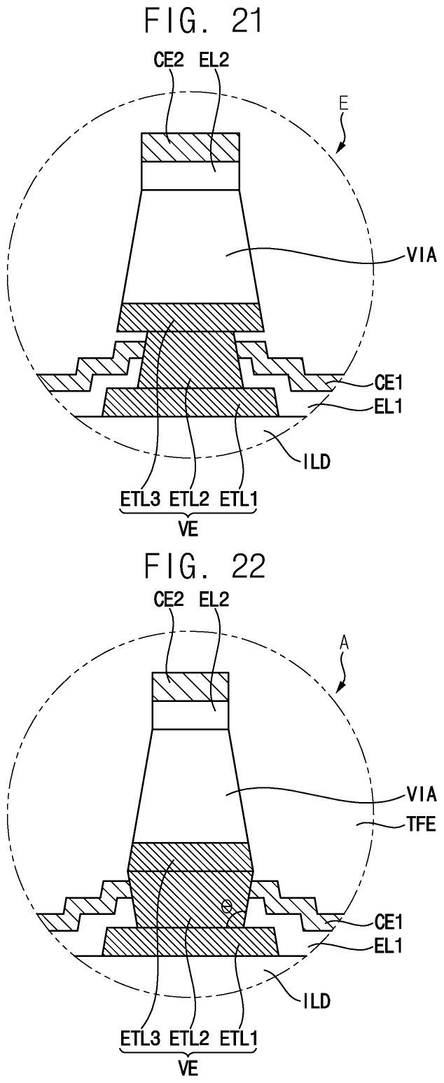

FIGS. 12, 13, 14, 15, 16, 17, 18, 19, 20 and 21 are cross-sectional views for explaining a method of manufacturing the display device of FIG. 2. For example, FIG. 13 may be an enlarged cross-sectional view of area B of FIG. 12, and FIG. 16 may be an enlarged cross-sectional view of area C of FIG. 15. FIG. 19 may be an enlarged cross-sectional view of area D of FIG. 18, and FIG. 21 may be an enlarged cross-sectional view of area E of FIG. 20.

Referring to FIGS. 12 and 13, the lower metal pattern BML, the buffer layer BFR, the active pattern ACT, the gate insulating layer GI, the gate electrode GE, the interlayer insulating layer ILD and a preliminary layer PL may be sequentially formed on the substrate SUB.

The preliminary layer PL may include a first preliminary layer PL1, a second preliminary layer PL2 disposed on the first preliminary layer PL1 and a third preliminary layer PL3 disposed on the second preliminary layer PL2. The first preliminary layer PL1 and the third preliminary layer PL3 may have a good etching selectivity to the second preliminary layer PL2. For example, the second preliminary layer PL2 may have a greater etch rate than the first preliminary layer PL1 and the third preliminary layer PL3 to a specific etchant. For example, each of the first preliminary layer PL1 and the third preliminary layer PL3 may include titanium, and the second preliminary layer PL2 may include aluminum, but the present disclosure is not limited thereto.

Referring to FIGS. 12, 13 and 14, the preliminary layer PL may be patterned to form the first connection electrode SD1, the second connection electrode SD2 and a preliminary power electrode P_VE.

Accordingly, the thin film transistor TFT including the lower metal pattern BML, the active pattern ACT, the gate electrode GE, the first connection electrode SD1 and the second connection electrode SD2 may be formed. The preliminary power electrode P_VE may be formed to be spaced apart from the thin film transistor TFT.

Referring to FIGS. 13, 14, 15 and 16, the preliminary power electrode P_VE may be etched to form the power electrode VE.

The power electrode VE may include the first electrode layer ETL1 formed from the first preliminary layer PL1, the second electrode layer ETL2 formed from the second preliminary layer PL2 and the third electrode layer ETL3 formed from the third preliminary layer PL3.

In an embodiment, the second electrode layer ETL2 may be etched so that the side surface of each of the first electrode layer ETL1 and the third electrode layer ETL3 may protrude from the side surface of the second electrode layer ETL2. Because the second preliminary layer PL2 may have a greater etch rate than the first preliminary layer PL1 and the third preliminary layer PL3 to a specific etchant, the second preliminary layer PL2 is etched more than the first preliminary layer PL1 and the third preliminary layer PL3 to form a undercut portion in the second preliminary layer PL2.

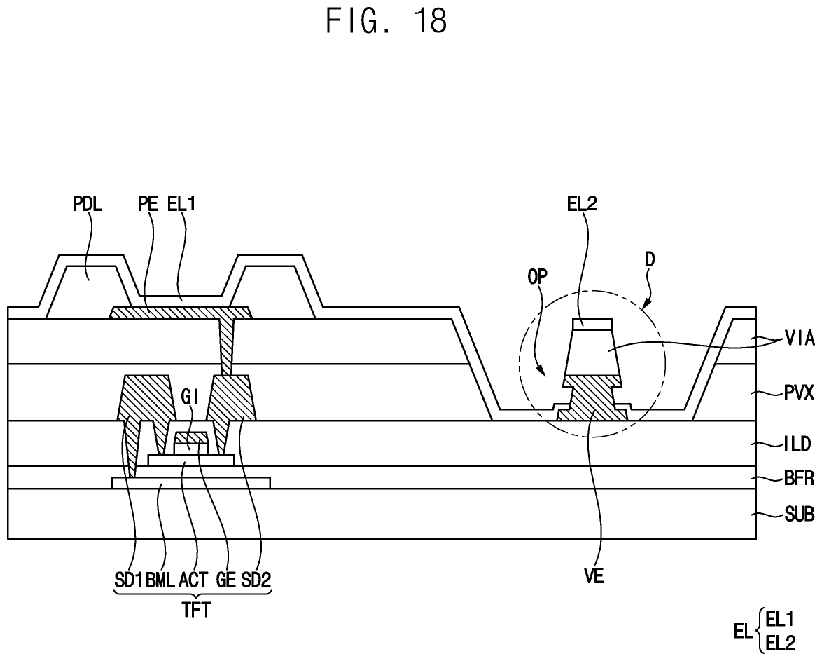

Referring to FIG. 17, the passivation layer PVX may be formed on the interlayer insulating layer ILD. The passivation layer PVX may be formed to cover the first connection electrode SD1 and the second connection electrode SD2, and expose the power electrode VE.

The via insulating layer VIA may be formed on each of the passivation layer PVX and the power electrode VE. The opening OP exposing a portion of the upper surface of the interlayer insulating layer ILD and the power electrode VE may be formed in the passivation layer PVX and the via insulating layer VIA.

The pixel electrode PE and the pixel defining layer PDL may be sequentially formed on the via insulating layer VIA. Each of the pixel electrode PE and the pixel defining layer PDL may be formed to be spaced apart from the power electrode VE.

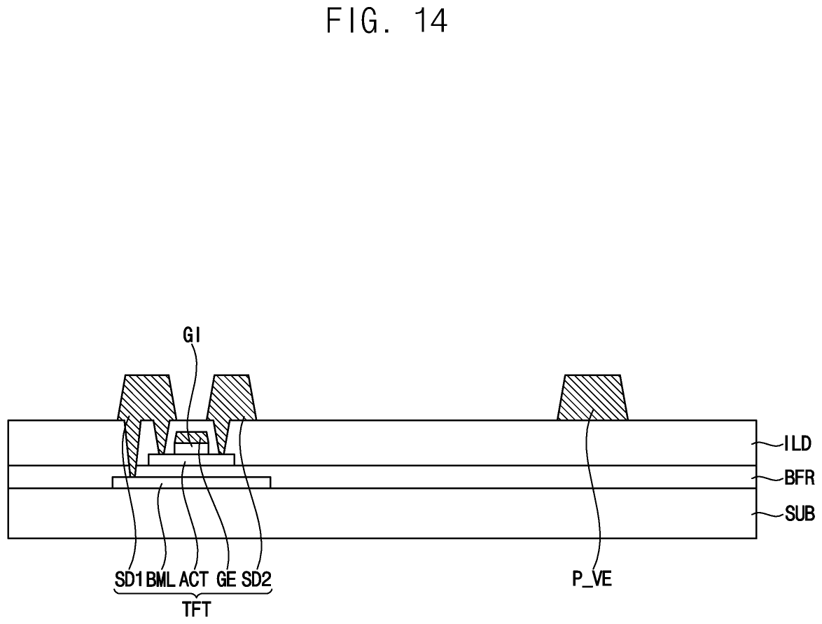

Although FIGS. 14, 15, 16 and 17 illustrate that the preliminary power electrode P_VE is etched to form the power electrode VE before the passivation layer PVX is formed, the present disclosure is not limited thereto. For example, the preliminary power electrode P_VE may be etched to form the power electrode VE after the passivation layer PVX is formed. In this case, an additional process for forming the photoresist to cover the first connection electrode SD1 and the second connection electrode SD2 for etching the preliminary power electrode P_VE may be omitted.

Referring to FIGS. 18 and 19, the light emitting layer EL may be formed on the pixel electrode PE, the pixel defining layer PDL and the via insulating layer VIA. In addition, the light emitting layer EL may be formed on the interlayer insulating layer ILD and the power electrode VE exposed by the opening OP.

The light emitting layer EL may include the first light emitting layer EL1 and the second light emitting layer EL2 spaced apart from the first light emitting layer EL1. The first light emitting layer EL1 may be formed on the pixel electrode PE, the pixel defining layer PDL and the interlayer insulating layer ILD, and the second light emitting layer EL2 may be formed on the power electrode VE. In an embodiment, the first light emitting layer EL1 may be formed to contact the side surface of each of the first electrode layer ETL1 and the second electrode layer ETL2. When forming the light emitting layer EL, the light emitting layer EL is disconnected to have the first light emitting layer EL1 and the second light emitting layer EL2 spaced apart from the first light emitting layer EL1 due to the undercut potion formed in the second electrode layer ETL2.

Referring to FIGS. 20 and 21, the common electrode CE may be formed on the light emitting layer EL.

The common electrode CE may include the first common electrode CE1 and the second common electrode CE2 spaced apart from the first common electrode CE1. The first common electrode CE1 may be formed on the first light emitting layer EL1, and the second common electrode CE2 may be formed on the second light emitting layer EL2. In an embodiment, the first common electrode CE1 may be formed to contact the side surface of the second electrode layer ETL2. When forming the common electrode CE, the common electrode CE is disconnected to have the first common electrode CE1 and the second common electrode CE2 spaced apart from the first common electrode CE1 due to the undercut potion formed in the second electrode layer ETL2.

Referring back to FIG. 2, the thin film encapsulation layer TFE may be formed on the common electrode CE. Accordingly, the display device 10 illustrated in FIG. 2 may be manufactured.

FIG. 22 is a cross-sectional view illustrating another example of FIG. 3. For example, FIG. 22 may be an enlarged cross-sectional view of the power electrode VE included in the display device 10.

Hereinafter, descriptions overlapping those of the power electrode VE described with reference to FIGS. 1, 2 and 3 will be omitted or simplified.

Referring to FIG. 22, the power electrode VE may include the first electrode layer ETL1, the second electrode layer ETL2 disposed on the first electrode layer ETL1 and the third electrode layer ETL3 disposed on the second electrode layer ETL2.

In an embodiment, the angle θ of the side surface of the second electrode layer ETL2 with respect to the upper surface of the first electrode layer ETL1 in a cross-sectional view may be about 90 degrees or more and about 150 degrees or less.

The side surface of the first electrode layer ETL1 may protrude from the side surface of the second electrode layer ETL2. However, the side surface of the third electrode layer ETL3 may not protrude from the side surface of the second electrode layer ETL2.

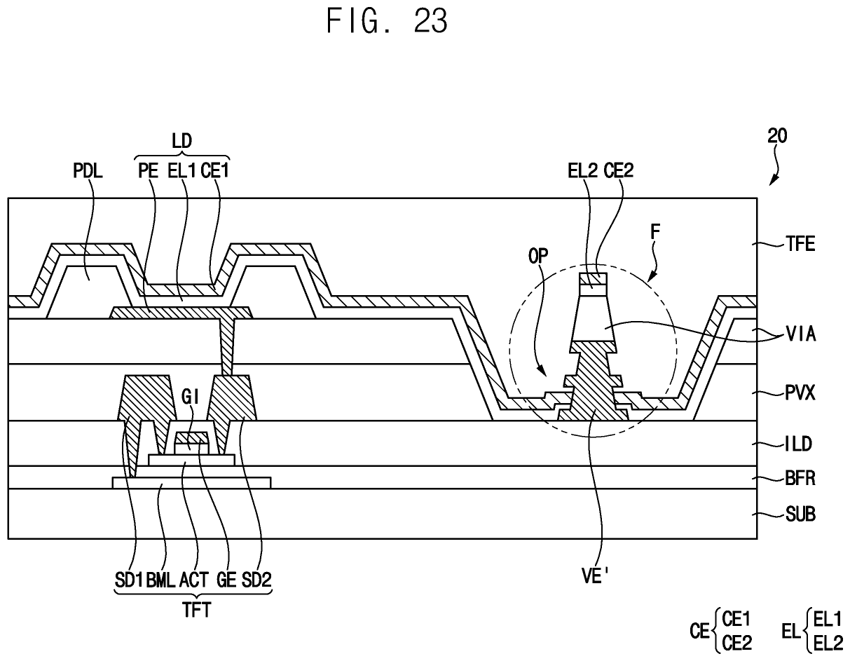

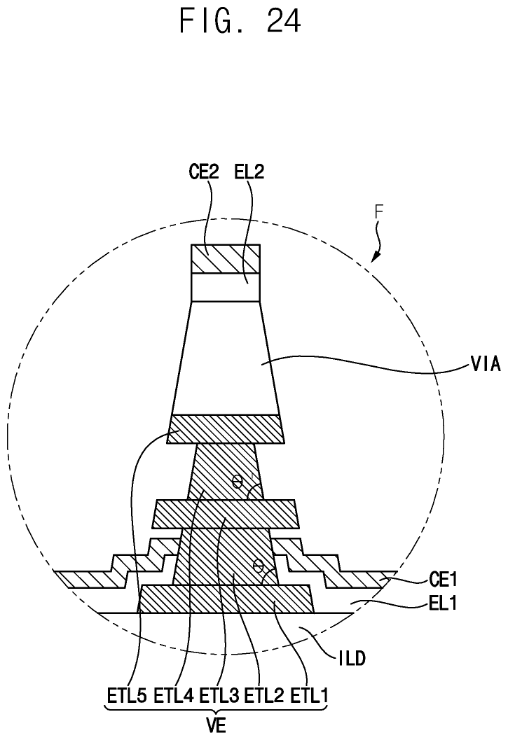

FIG. 23 is a cross-sectional view illustrating a portion of a display device according to another embodiment of the present disclosure. FIG. 24 is an enlarged cross-sectional view of area F of FIG. 23. For example, FIG. 24 may be an enlarged cross-sectional view of a power electrode VE′ included in a display device 20.

Referring to FIGS. 23 and 24, the display device 20 may include a substrate SUB, a lower metal pattern BML, a buffer layer BFR, an active pattern ACT, a gate insulating layer GI, a gate electrode GE, an interlayer insulating layer ILD, a first connection electrode SD1, a second connection electrode SD2, the power electrode VE′, a passivation layer PVX, a via insulating layer VIA, a pixel electrode PE, a pixel defining layer PDL, a light emitting layer EL, a common electrode CE and a thin film encapsulation layer TFE.

Hereinafter, descriptions overlapping those of the display device 10 described with reference to FIGS. 1, 2 and 3 will be omitted or simplified.

The power electrode VE′ may be disposed on the interlayer insulating layer ILD.

In an embodiment, the power electrode VE′ may include a first electrode layer ETL1, a second electrode layer ETL2 disposed on the first electrode layer ETL1, a third electrode layer ETL3 disposed on the second electrode layer ETL2, a fourth electrode layer ETL4 disposed on the third electrode layer ETL3 and a fifth electrode layer ETL5 disposed on the fourth electrode layer ETL4.

A side surface of each of the first electrode layer ETL1, the third electrode layer ETL3 and the fifth electrode layer ETL5 may protrude from a side surface of each of the second electrode layer ETL2 and the fourth electrode layer ETL4. However, the present disclosure is not limited thereto. For example, the side surface of the fifth electrode layer ETL5 may not protrude from the side surface of each of the second electrode layer ETL2 and the fourth electrode layer ETL4.

In an embodiment, the second electrode layer ETL2 may have a tapered or reverse tapered shape with respect to the first electrode layer ETL1 in a cross-sectional view. Specifically, an angle θ of the side surface of the second electrode layer ETL2 with respect to an upper surface of the first electrode layer ETL1 in cross-sectional view may be about 10 degrees or more and about 150 degrees or less. In addition, the fourth electrode layer ETL4 may have a tapered or reverse tapered shape with respect to the third electrode layer ETL3 in a cross-sectional view. Specifically, an angle θ′ of the side surface of the fourth electrode layer ETL4 with respect to an upper surface of the third electrode layer ETL3 in a cross-sectional view may be about 10 degrees or more and about 150 degrees or less.

Each of the first, second, third, fourth and fifth electrode layers ETL1, ETL2, ETL3, ETL4 and ETL5 may include materials different from each other. However, the present disclosure is not limited thereto. For example, each of the first, second, third, fourth and fifth electrode layers ETL1, ETL2, ETL3, ETL4 and ETL5 may include a same material as each other.

Although FIGS. 23 and 24 illustrate that the power electrode VE includes five electrode layers, the present disclosure is not limited thereto. For example, the power electrode VE may include 6 or more electrode layers.

The display device 20 according to an embodiment of the present disclosure may include the power electrode VE′ including the first electrode layer ETL1, the second electrode layer ETL2, the third electrode layer ETL3, the fourth electrode layer ETL4 and the fifth electrode layer ETL5, and the common electrode CE. The common electrode CE may be connected to the power electrode VE′ by contacting a side surface of the power electrode VE′. Accordingly, a voltage drop in the common electrode CE and IR drop may be prevented. In addition, since the common electrode CE may be connected to the power electrode VE′ without a separate laser drilling process or a photo process using a separate mask, an efficiency of a manufacturing process may be improved.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate;
a transistor disposed on the substrate;
a power electrode disposed on the substrate;
a pixel electrode disposed on the transistor;
a light emitting layer disposed on each of the pixel electrode and the power electrode; and
a common electrode disposed on the light emitting layer,
wherein the power electrode includes a stem part extending in a first direction and at least one first branch part protruding from the stem part in a second direction crossing the first direction in a plan view, and
wherein the first branch part has a shape in which a width decreases as a distance from the stem part increases in a plan view.

2. The display device of claim 1, wherein the power electrode further includes at least one second branch part protruding from the stem part in a third direction opposite to the second direction in a plan view.

3. The display device of claim 2, wherein the first branch part and the second branch part are symmetrical to each other with respect to the stem part in a plan view.

4. The display device of claim 2, wherein the first branch part and the second branch part are asymmetrical to each other with respect to the stem part in a plan view.

5. The display device of claim 1, wherein the power electrode includes:
a first electrode layer;
a second electrode layer disposed on the first electrode layer; and
a third electrode layer disposed on the second electrode layer,
wherein a side surface of the first electrode layer protrudes from a side surface of the second electrode layer.

6. The display device of claim 5, wherein a side surface of the third electrode layer protrudes from the side surface of the second electrode layer.

7. The display device of claim 5, wherein the side surface of the second electrode layer forms an angle of about 10 degrees or more and about 150 degrees or less with respect to an upper surface of the first electrode layer in a cross-sectional view.

8. The display device of claim 5, wherein the light emitting layer includes:
a first light emitting layer disposed on the pixel electrode; and
a second light emitting layer disposed on the power electrode and spaced apart from the first light emitting layer, and
wherein the first light emitting layer contacts the side surface of the second electrode layer.

9. The display device of claim 8, wherein the common electrode includes:
a first common electrode disposed on the first light emitting layer and covering the first light emitting layer; and
a second common electrode disposed on the power electrode and spaced apart from the first common electrode, and
wherein the first common electrode contacts the side surface of the second electrode layer.

10. The display device of claim 5, wherein the power electrode further includes:
at least one fourth electrode layer disposed on the third electrode layer; and
at least one fifth electrode layer disposed on the fourth electrode layer, and
wherein a side surface of the third electrode layer protrudes from a side surface of the fourth electrode layer.

11. The display device of claim 5, wherein at least one of the first, second and third electrode layers includes a metal.

12. The display device of claim 5, wherein at least one of the first, second and third electrode layers includes a transparent conductive oxide.

13. The display device of claim 5, wherein at least one of the first, second and third electrode layers includes an organic material.

14. The display device of claim 1, wherein a ratio of a length of the power electrode in the first direction to a length of the power electrode in the second direction in a plan view is about 1:20 to about 20:1.

15. A display device comprising:
a substrate;
a transistor disposed on the substrate;
a power electrode disposed on the substrate;
a pixel electrode disposed on the transistor;
a light emitting layer disposed on each of the pixel electrode and the power electrode; and
a common electrode disposed on the light emitting layer,
wherein the power electrode includes a stem part extending in a first direction and a branch part protruding from the stem part in a plan view, and
wherein the branch part includes at least one first branch part protruding in a second direction crossing the first direction and at least one second branch part protruding in a third direction crossing at least one of the first direction and the second direction.

16. The display device of claim 15, wherein the power electrode includes:
a first electrode layer;
a second electrode layer disposed on the first electrode layer; and
a third electrode layer disposed on the second electrode layer, and
wherein a side surface of the first electrode layer protrudes from a side surface of the second electrode layer.

17. The display device of claim 16, wherein a side surface of the third electrode layer protrudes from the side surface of the second electrode layer.

18. The display device of claim 16, wherein the side surface of the second electrode layer forms an angle of about 10 degrees or more and about 150 degrees or less with respect to an upper surface of the first electrode layer in a cross-sectional view.

19. The display device of claim 16, wherein the light emitting layer includes:
a first light emitting layer disposed on the pixel electrode; and
a second light emitting layer disposed on the power electrode and spaced apart from the first light emitting layer, and
wherein the first light emitting layer contacts the side surface of the second electrode layer.

20. The display device of claim 19, wherein the common electrode includes:
a first common electrode disposed on the first light emitting layer and covering the first light emitting layer; and
a second common electrode disposed on the power electrode and spaced apart from the first common electrode, and
wherein the first common electrode contacts the side surface of the second electrode layer.
